(19) United States
(12) Patent Application Publication
(10) Pub. No.: US 2025/0120268 A1
(43) Pub. Date: Apr. 10, 2025

(54) DISPLAY DEVICE

(71) Applicant: Samsung Display Co., LTD., Yongin-si (KR)

(72) Inventors: Tae Hyoung NO, Yongin-si (KR); Joon Dong KIM, Yongin-si (KR); Min Cheol LEE, Yongin-si (KR); Kwang Chul JUNG, Yongin-si (KR); Yong Jun JO, Yongin-si (KR)

(21) Appl. No.: 18/664,135

(22) Filed: May 14, 2024

(30) Foreign Application Priority Data
Oct. 6, 2023 (KR) 10-2023-0133831

(51) Int. Cl. H10K 59/131

(52) U.S. Cl. CPC H10K 59/131

(57) ABSTRACT

A display device includes a substrate, a circuit layer, and an element layer. The circuit layer includes: light emitting pixel drivers; data lines; demux circuits outputting the data signal of the data lines based on a data mux signal supplied from a display driving circuit; and data transmission lines electrically connected between the display driving circuit and the demux circuits, and transmitting data mux signals of the demux circuits, respectively. The data transmission lines include: a first data transmission line electrically connected to a first demux circuit adjacent to an edge of the substrate in a first direction; and a second data transmission line electrically connected to a second demux circuit spaced further apart from the edge of the substrate than the first demux circuit in the first direction. The second data transmission line is electrically connected to a path compensation capacitor in the sub-region.

### CROSS-REFERENCE TO RELATED APPLICATION

The present application claims priority to and the benefit of Korean Patent Application No. 10-2023-0133831 filed on Oct. 6, 2023, in the Korean Intellectual Property Office, the entire content of which is incorporated herein by reference.

### BACKGROUND

### 1. Field

Aspects of some embodiments of the present disclosure relate to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

One surface of the display device may be a display surface including a display area in which an image is displayed and a non-display area that is a periphery of the display area. Emission areas emitting light with respective luminances and colors may be arranged in the display area.

The above information disclosed in this Background section is only for enhancement of understanding of the background and therefore the information discussed in this Background section does not necessarily constitute prior art.

### SUMMARY

As the display device becomes higher resolution or larger, the number of data lines may increase, and the difference in length of transmission paths between a display driving circuit and the data lines may increase. As a result, a distorted or delayed data signal may be supplied to data lines with a relatively long transmission path among the data lines, resulting in degraded display quality due to luminance deviations.

In view of the above, aspects of the present disclosure provide a display device that may relatively improve display quality by reducing luminance deviations caused by the difference in length of transmission paths between the display driving circuit and the data lines.

According to some embodiments of the present disclosure, a display device includes a substrate, a circuit layer on the substrate, and an element layer on the circuit layer. According to some embodiments, the substrate comprises a main region comprising a display area in which emission areas are arranged and a non-display area around the display area, and a sub-region protruding from one side of the main region. According to some embodiments, the element layer comprises light emitting elements respectively in the emission areas. According to some embodiments, the circuit layer comprises: light emitting pixel drivers electrically connected to the light emitting elements, respectively, and arranged in a first direction and a second direction; data lines extending in the second direction, and transmitting a data signal to the light emitting pixel drivers; demux circuits in the non-display area, and outputting the data signal of the data lines based on a data mux signal supplied from a display driving circuit; and data transmission lines electrically connected between the display driving circuit and the demux circuits, and transmitting data mux signals of the demux circuits, respectively. According to some embodiments, the data transmission lines comprise: a first data transmission line electrically connected to a first demux circuit adjacent to an edge of the substrate in the first direction; and a second data transmission line electrically connected to a second demux circuit spaced further apart from the edge of the substrate than the first demux circuit in the first direction. According to some embodiments, the second data transmission line is electrically connected to a path compensation capacitor in the sub-region.

According to some embodiments, the data lines comprise: first data lines electrically connected to demux output lines of the first demux circuit; and second data lines electrically connected to demux output lines of the second demux circuit. According to some embodiments, the circuit layer further comprises: a first bypass auxiliary line extending in the second direction, paired with one of the second data lines, and electrically connected to the first data transmission line; a second bypass auxiliary line extending in the first direction, and electrically connected to the first bypass auxiliary line; a third bypass auxiliary line extending in the second direction, paired with one of the first data lines, and electrically connected to the second bypass auxiliary line; and an input auxiliary line in the non-display area, and electrically connected between the third bypass auxiliary line and the first demux circuit. According to some embodiments, the second data transmission line is directly electrically connected to the second demux circuit.

According to some embodiments, the sub-region comprises a bending region which is transformed into a bent shape, a first sub-region between the main region and one side of the bending region, and a second sub-region connected to the other side of the bending region. According to some embodiments, the display driving circuit is in the second sub-region. According to some embodiments, the circuit layer further comprises a power pad line extending from a part of the signal pads in the second sub-region to the bending region. According to some embodiments, each of the data transmission lines comprises: a data output line in the second sub-region, and extending from the display driving circuit to the bending region; a data bending line in the bending region, and electrically connected to the data output line; and a data input line in the first sub-region and the non-display area, and electrically connected to the data bending line. According to some embodiments, the path compensation capacitor is electrically connected between the data output line of the second data transmission line and the power pad line.

According to some embodiments, the data transmission lines further comprise a third data transmission line electrically connected to a third demux circuit spaced further apart from the edge of the substrate than the second demux circuit in the first direction. According to some embodiments, the data output line of the second data transmission line is electrically connected to a first path compensation capacitor. According to some embodiments, the data output line of the third data transmission line is electrically connected to a second path compensation capacitor having a larger capacitance than that of the first path compensation capacitor and in the sub-region.

According to some embodiments, the circuit layer further comprises a compensation capacitor electrode in the second sub-region and electrically connected to the data output line of the second data transmission line. According to some embodiments, the path compensation capacitor is provided by an overlapping area between the power pad line and each of the compensation capacitor electrode and the data output line of the second data transmission line.

According to some embodiments, the circuit layer comprises: a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a first source-drain conductive layer on the first interlayer insulating layer; and a first planarization layer covering the first source-drain conductive layer. According to some embodiments, the first source-drain conductive layer comprises the data output line of each of the data transmission lines.

According to some embodiments, the first gate conductive layer comprises the power pad line. According to some embodiments, the second gate conductive layer comprises the compensation capacitor electrode. According to some embodiments, the compensation capacitor electrode is electrically connected to the data output line of the second data transmission line through at least one capacitor auxiliary contact hole penetrating the first interlayer insulating layer.

According to some embodiments, the first gate conductive layer comprises the compensation capacitor electrode. According to some embodiments, the second gate conductive layer comprises the power pad line. According to some embodiments, the compensation capacitor electrode is electrically connected to the data output line of the second data transmission line through at least one capacitor auxiliary contact hole penetrating the second gate insulating layer and the first interlayer insulating layer.

According to some embodiments, the circuit layer further comprises: a second semiconductor layer on the first interlayer insulating layer; a third gate insulating layer covering the second semiconductor layer; a third gate conductive layer on the third gate insulating layer; and a second interlayer insulating layer covering the third gate conductive layer. According to some embodiments, the first source-drain conductive layer is on the second interlayer insulating layer.

According to some embodiments, the compensation capacitor electrode comprises a first capacitor division electrode and a second capacitor division electrode in different conductive layers. According to some embodiments, the first gate conductive layer comprises the first capacitor division electrode. According to some embodiments, the second gate conductive layer comprises the power pad line. According to some embodiments, the third gate conductive layer comprises the second capacitor division electrode. According to some embodiments, the first capacitor division electrode is electrically connected to the data output line of the second data transmission line through at least one capacitor auxiliary contact hole penetrating the second interlayer insulating layer, the third gate insulating layer, the first interlayer insulating layer, and the second gate insulating layer. According to some embodiments, the second capacitor division electrode is electrically connected to the data output line of the second data transmission line through at least one second capacitor auxiliary contact hole penetrating the second interlayer insulating layer.

According to some embodiments, the power pad line comprises a first pad division line and a second pad division line in different conductive layers. According to some embodiments, the first gate conductive layer comprises the first pad division line. According to some embodiments, the second gate conductive layer comprises the compensation capacitor electrode. According to some embodiments, the third gate conductive layer comprises the second pad division line. According to some embodiments, the compensation capacitor electrode is electrically connected to the data output line of the second data transmission line through at least one capacitor auxiliary contact hole penetrating the first interlayer insulating layer.

According to some embodiments, the power pad line comprises: a first power pad line transmitting a first power; and a second power pad line transmitting a second power. According to some embodiments, the first power and the second power are provided for driving the light emitting element.

According to some embodiments, each of the demux circuits comprises demux transistors electrically connected between one of the data transmission lines and two or more of the data lines. According to some embodiments, the demux transistors comprise: a first demux transistor turned on by a first demux control signal; and a second demux transistor turned on by a second demux control signal.

According to some embodiments of the present disclosure, there is provided a display device comprises a substrate, a circuit layer on the substrate, and an element layer on the circuit layer. According to some embodiments, the substrate comprises a main region comprising a display area in which emission areas are arranged and a non-display area around the display area, and a sub-region protruding from one side of the main region. According to some embodiments, the element layer comprises light emitting elements respectively in the emission areas. According to some embodiments, the circuit layer comprises: light emitting pixel drivers electrically connected to the light emitting elements, respectively, and arranged in a first direction and a second direction; data lines extending in the second direction, and transmitting a data signal to the light emitting pixel drivers; demux circuits in the non-display area, and outputting the data signal of the data lines based on a data mux signal supplied from a display driving circuit; and data transmission lines electrically connected between the display driving circuit and the demux circuits, and transmitting data mux signals of the demux circuits, respectively. According to some embodiments, the demux circuits comprise a first demux circuit adjacent to an edge of the substrate in the first direction, and a second demux circuit spaced further apart from the edge of the substrate than the first demux circuit in the first direction. According to some embodiments, the data transmission lines comprise a first data transmission line transmitting a data mux signal of the first demux circuit, and a second data transmission line transmitting a data mux signal of the second demux circuit. According to some embodiments, the first data transmission line is electrically connected to the first demux circuit through a bypass line in the display area and an input auxiliary line in the non-display area. According to some embodiments, the second data transmission line is directly electrically connected to the second demux circuit, and electrically connected to a path compensation capacitor in the sub-region.

According to some embodiments, the sub-region comprises a bending region which is transformed into a bent shape, a first sub-region between the main region and one side of the bending region, and a second sub-region connected to the other side of the bending region. According to some embodiments, the display driving circuit is in the second sub-region. According to some embodiments, the circuit layer further comprises a power pad line extending from a part of signal pads in the second sub-region to the bending region. Each of the data transmission lines comprises: a data output line in the second sub-region, and extending from the display driving circuit to the bending region; a data bending line in the bending region, and electrically connected to the data output line; and a data input line in the first sub-region and the non-display area, and electrically connected to the data bending line. According to some embodiments, the path compensation capacitor is electrically connected between the data output line of the second data transmission line and the power pad line.

According to some embodiments, the demux circuits further comprise a third demux circuit spaced further apart from the edge of the substrate than the second demux circuit in the first direction. According to some embodiments, the data transmission lines further comprise a third data transmission line transmitting a data mux signal of the third demux circuit. According to some embodiments, the circuit layer further comprises: a first compensation capacitor electrode in the second sub-region, overlapping the power pad line, and electrically connected to the data output line of the second data transmission line; and a second compensation capacitor electrode in the second sub-region, overlapping the power pad line, and electrically connected to the data output line of the second data transmission line. According to some embodiments, an overlapping area between the second compensation capacitor electrode and the power pad line has a larger width than that of an overlapping area between the first compensation capacitor electrode and the power pad line.

According to some embodiments, the path compensation capacitor is provided by an overlapping area between the power pad line and each of the data output line of the second data transmission line and the compensation capacitor electrode electrically connected to the data output line of the second data transmission line. According to some embodiments, the circuit layer comprises: a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a first source-drain conductive layer on the first interlayer insulating layer; and a first planarization layer covering the first source-drain conductive layer. According to some embodiments, the first source-drain conductive layer comprises the data output line of each of the data transmission lines. According to some embodiments, one of the first gate conductive layer and the second gate conductive layer comprises the power pad line. According to some embodiments, the other of the first gate conductive layer and the second gate conductive layer comprises the compensation capacitor electrode.

According to some embodiments, the path compensation capacitor is provided by an overlapping area between the power pad line and each of the data output line of the second data transmission line and the compensation capacitor electrode electrically connected to the data output line of the second data transmission line. According to some embodiments, the circuit layer comprises: a first semiconductor layer on the substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a second semiconductor layer on the first interlayer insulating layer; a third gate insulating layer covering the second semiconductor layer; a third gate conductive layer on the third gate insulating layer; a second interlayer insulating layer covering the third gate conductive layer; a first source-drain conductive layer on the second interlayer insulating layer; and a first planarization layer covering the first source-drain conductive layer. According to some embodiments, the first source-drain conductive layer comprises the data output line of each of the data transmission lines.

According to some embodiments, the compensation capacitor electrode comprises a first capacitor division electrode and a second capacitor division electrode in different conductive layers. According to some embodiments, the first gate conductive layer comprises the first capacitor division electrode. According to some embodiments, the second gate conductive layer comprises the power pad line. According to some embodiments, the third gate conductive layer comprises the second capacitor division electrode.

According to some embodiments, the power pad line comprises a first pad division line and a second pad division line in different conductive layers. According to some embodiments, the first gate conductive layer comprises the first pad division line. According to some embodiments, the second gate conductive layer comprises the compensation capacitor electrode. According to some embodiments, the third gate conductive layer comprises the second pad division line.

According to some embodiments, the display device may include a substrate, a circuit layer, and an element layer. According to some embodiments, the circuit layer may include light emitting pixel drivers electrically connected to the light emitting elements, respectively, and arranged in a first direction and a second direction, data lines extending in the second direction and transmitting a data signal to the light emitting pixel drivers, demux circuits outputting the data signal of the data lines based on a data mux signal supplied from a display driving circuit, and data transmission lines electrically connected between the display driving circuit and the demux circuits. According to some embodiments, the data transmission lines may include a first data transmission line electrically connected to a first demux circuit adjacent to an edge of the substrate in the first direction, and a second data transmission line transmitting a data mux signal of a second demux circuit spaced further apart from the edge of the substrate than the first demux circuit in the first direction. According to some embodiments, the second data transmission line may be electrically connected to a path compensation capacitor.

That is, because a second demux circuit is located closer to the display driving circuit than a first demux circuit, a second data transmission line may have a shorter length than a first data transmission line.

According to some embodiments, the substrate may include a main region including a display area in which emission areas are arranged and a non-display area around the display area, and a sub-region protruding from one side of the main region.

According to some embodiments, the demux circuits may be in the non-display area, and the display driving circuit may be in the sub-region.

According to some embodiments, the first data transmission line may be electrically connected to the first demux circuit through a bypass line in the display area and an input auxiliary line in the non-display area.

Accordingly, due to the bypass line and the input auxiliary line, the difference in length of transmission paths electrically connecting the display driving circuit to the first and second demux circuits may increase.

However, according to some embodiments, the second data transmission line may be electrically connected to a path compensation capacitor, so that the luminance deviation caused by the difference in length of the transmission paths may be compensated. As a result, the display quality of the display device may be relatively improved.

However, the characteristics of embodiments of the present disclosure are not limited to those described above and various other effects are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating the display device of FIG. 1 according to some embodiments;

FIG. 3 is a cross-sectional view taken along the line A-A′ of FIG. 2 according to some embodiments;

FIG. 4 is a layout diagram illustrating part B of FIG. 2 according to some embodiments;

FIG. 5 is an equivalent circuit diagram showing the light emitting pixel driver of FIG. 4 according to some embodiments;

FIG. 6 is a cross-sectional view illustrating a first transistor, a sixth transistor, and a light emitting element shown in FIG. 5 according to some embodiments;

FIG. 7 is a plan view illustrating the substrate of FIG. 3 according to some embodiments;

FIG. 8 is a layout diagram showing part C of FIG. 7 according to some embodiments;

FIG. 9 is a cross-sectional view taken along the line D-D′ of FIG. 8 according to some embodiments;

FIG. 10 is an equivalent circuit diagram showing a transmission path between a display driving circuit and a first demux circuit of FIG. 8 according to some embodiments;

FIG. 11 is an equivalent circuit diagram showing a transmission path between a display driving circuit and a second demux circuit of FIG. 8 according to some embodiments;

FIG. 12 is a plan view showing part E of FIG. 8 according to some embodiments;

FIG. 13 is a cross-sectional view taken along the line G-G′ of FIG. 12 according to some embodiments;

FIG. 14 is a plan view showing part F of FIG. 8 according to some embodiments;

FIG. 15 is a plan view showing part E of FIG. 8 according to some embodiments;

FIG. 16 is a cross-sectional view taken along the line G-G′ of FIG. 15 according to some embodiments;

FIG. 17 is an equivalent circuit diagram showing the light emitting pixel driver of FIG. 4 according to some embodiments;

FIG. 18 is a cross-sectional view showing the first transistor, the second transistor, the fourth transistor, the sixth transistor, and the light emitting element of FIG. 17 according to some embodiments;

FIG. 19 is a layout diagram showing part C of FIG. 7 according to some embodiments;

FIG. 20 is a plan view showing part H of FIG. according to some embodiments;

FIG. 21 is a cross-sectional view taken along the line I-I′ of FIG. 20 according to some embodiments;

FIG. 22 is a plan view showing part H of FIG. 19 according to some embodiments; and

FIG. 23 is a cross-sectional view taken along the line I-I′ of FIG. 22 according to some embodiments.

### DETAILED DESCRIPTION

Aspects of some embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, aspects of some embodiments will be described in more detail with reference to the accompanying drawings.

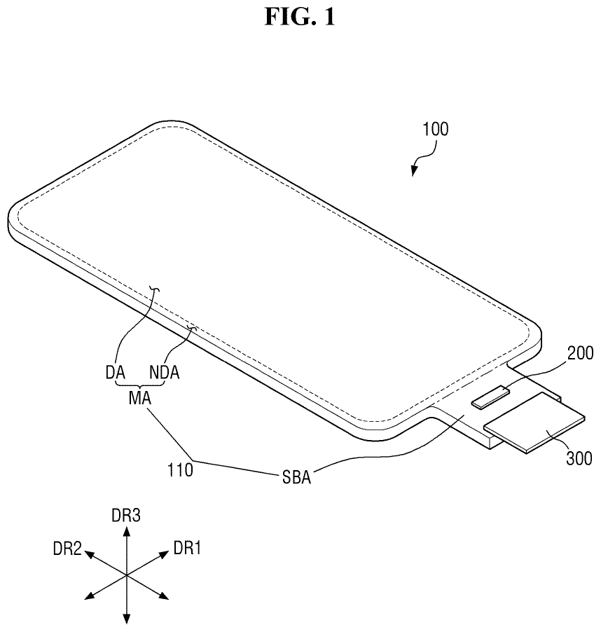

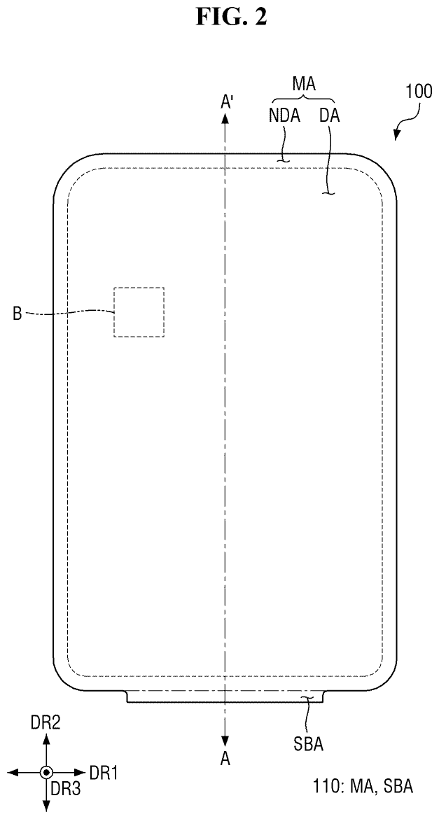

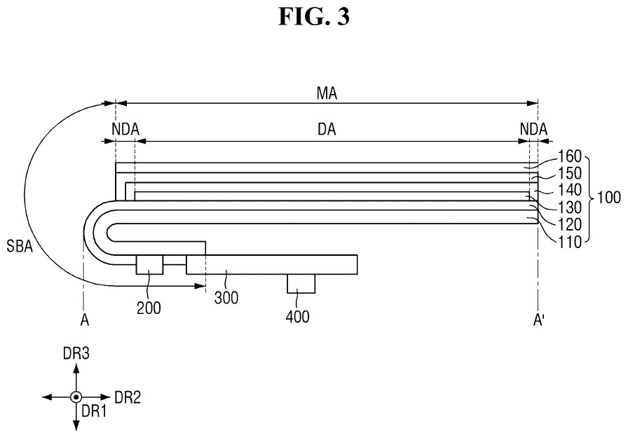

FIG. 1 is a perspective view illustrating a display device according to some embodiments. FIG. 2 is a plan view illustrating the display device of FIG. 1. FIG. 3 is a cross-sectional view taken along the line A-A′ of FIG. 2.

Referring to FIGS. 1 and 2, a display device 100 is a device for displaying a moving images (e.g., video images) or a still images (e.g., static images). The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, embodiments according to the present disclosure are not limited thereto, and may be applied to a display device including an organic insulating material, an organic light emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

As illustrated in FIGS. 1, 2 and 3, the display device 100 includes a substrate 110.

The substrate 110 may include a main region MA corresponding to a display surface of the display device 100 and a sub-region SBA protruding from one side of the main region MA.

As shown in FIG. 2, the main region MA may include a display area DA located at most of the center thereof, and a non-display area NDA located around (e.g., in a periphery, or outside a footprint of) the display area DA.

The display area DA may, in plan view, be formed in a rectangular shape having short sides in the first direction DR1 and long sides in the second direction DR2 crossing the first direction DR1. The corner where the short side in the first direction DR1 and the long side in the second direction DR2 meet may be rounded to have a curvature (e.g., a set or predetermined curvature) or may be right-angled. The planar shape of the display area DA is not limited to the rectangular shape, and may be formed in another polygonal shape, a circular shape or an elliptical shape.

The non-display area NDA may be located at the edge of the main region MA to surround the display area DA.

The sub-region SBA may be a region protruding from the non-display area NDA of the main region MA to one side in the second direction DR2.

Because a part of the sub-region SBA is transformed into a bent shape, another part of the sub-region SBA may be located on the rear surface of the display device 100.

FIGS. 2 and 3 illustrate the display device 100 with a part of the sub-region SBA in a bent state.

Referring to FIG. 3, the display device 100 according to some embodiments includes the substrate 110, a circuit layer 120 located on the substrate 110, and an element layer 130 located on the circuit layer 120.

The display device 100 according to some embodiments may further include an encapsulation layer 140 located on the element layer 130, and a touch sensor layer 150 located on the encapsulation layer 140.

Also, the display device 100 according to some embodiments may further include a polarization layer 160 located on the touch sensor layer 150 to reduce reflection of external light.

The substrate 110 may be formed of an insulating material such as a polymer resin. For example, the substrate 110 may be formed of polyimide. The substrate 110 may be a flexible substrate which can be bent, folded or rolled.

Alternatively, the substrate 110 may be formed of an insulating material such as glass or the like.

The substrate 110 may include the main region MA and the sub-region SBA. The main region MA may include the display area DA and the non-display area NDA.

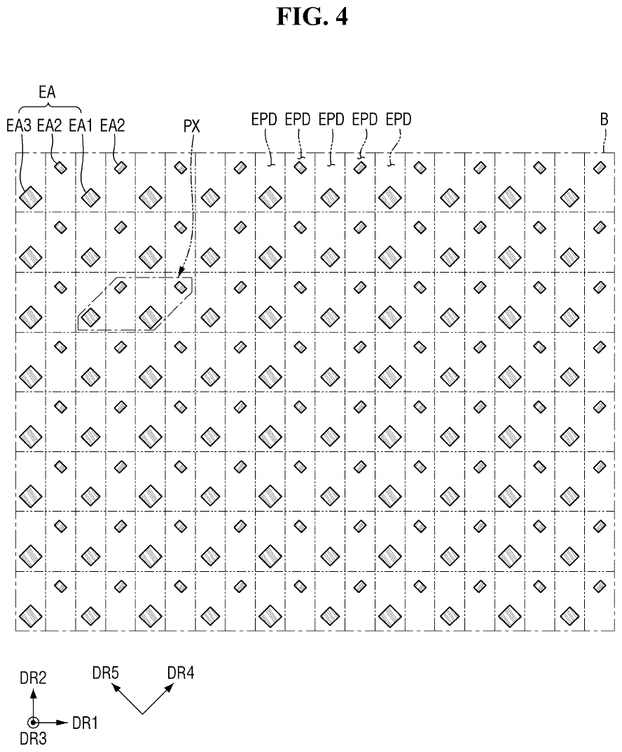

FIG. 4 is a layout diagram illustrating part B of FIG. 2.

Referring to FIG. 4, the display area DA of the display device 100 according to some embodiments may include the emission areas EA. In addition, the display area DA may further include a non-emission area located in a gap between the emission areas EA.

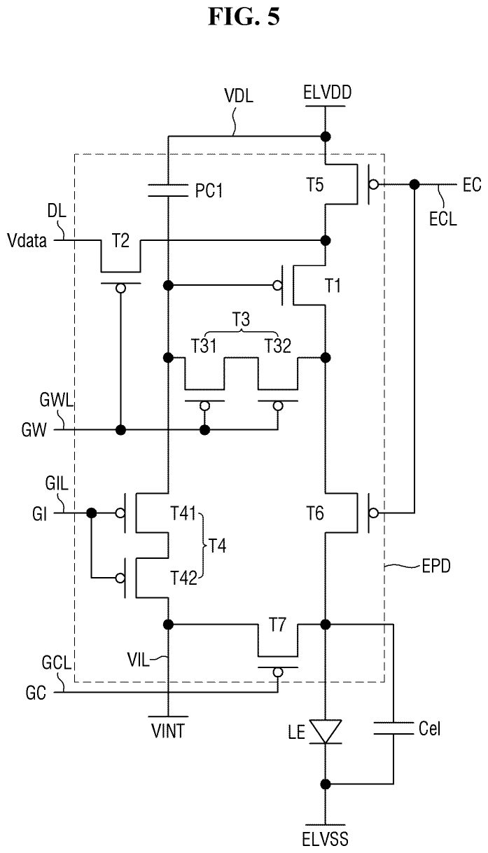

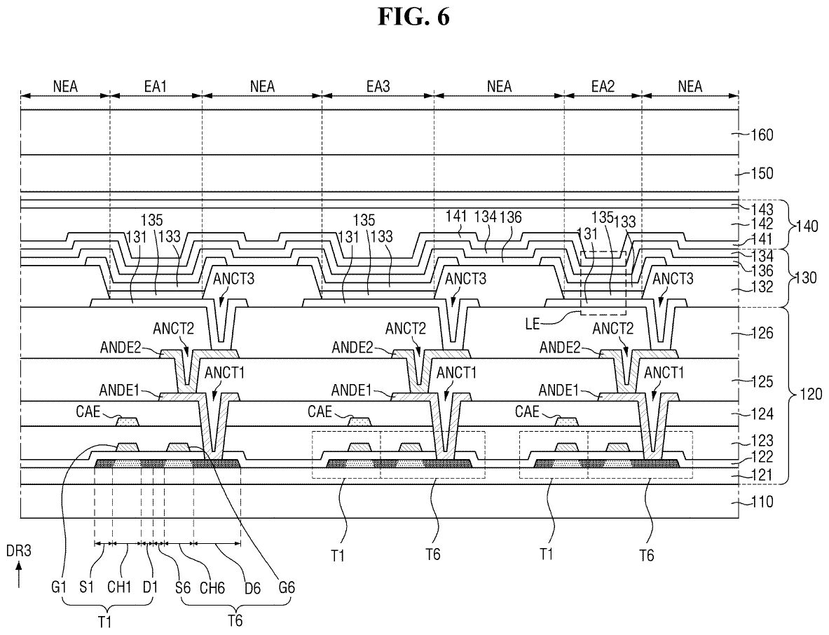

Light emitting pixel drivers EPD respectively corresponding to the emission areas EA may be arranged in the display area DA in parallel with each other in the first direction DR1 and the second direction DR2. The light emitting pixel drivers EPD may be respectively electrically connected to light emitting elements LE (see FIGS. 5 and 6) of the element layer 130 respectively located in the emission areas EA.

The emission areas EA may have a rhombus shape or a rectangular shape in plan view. However, this is only an example, and the planar shape of the emission areas EA is not limited to that illustrated in FIG. 4. That is, in a plan view, the emission areas EA may have a polygonal shape such as a square, a pentagon, a hexagon, etc., or may have a circular or elliptical shape including the edge of a curve.

The emission areas EA may include first emission areas EA1 emitting light of a first color in a wavelength band (e.g., a set or predetermined wavelength band), second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixels PX may be a basic unit for displaying various colors including white with a luminance (e.g., a set or predetermined luminance).

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 5 is an equivalent circuit diagram showing the light emitting pixel driver of FIG. 4 according to some embodiments.

Referring to FIG. 5, one of the light emitting elements LE of the element layer 130 may be electrically connected between one of the light emitting pixel drivers EPD of the circuit layer 120 and a second power ELVSS.

That is, an anode electrode 131 (see FIG. 6) of the light emitting element LE may be electrically connected to the light emitting pixel driver EPD, and a cathode electrode 134 (see FIG. 6) of the light emitting element LE may be applied with the second power ELVSS lower than a first power ELVDD.

A capacitor Cel connected in parallel with the light emitting element LE refers to a parasitic capacitance between the anode electrode 131 and the cathode electrode 134.

The circuit layer 120 may further include a first power line VDL for transmitting the first power ELVDD and an initialization power line VIL for transmitting an initialization power VINT.

The circuit layer 120 may further include a scan write line GWL for transmitting a scan write signal GW, a scan initialization line GIL for transmitting a scan initialization signal GI, an emission control line ECL for transmitting an emission control signal EC, and a gate control line GCL for transmitting a gate control signal GC.

One light emitting pixel driver EPD of the circuit layer 120 may include a first transistor T1 configured to generate a driving current for driving the light emitting element LE, two or more transistors T2 to T7 electrically connected to the first transistor T1, and at least one pixel capacitor PC1.

The first transistor T1 is connected in series with the light emitting element LE between the first power ELVDD and the second power ELVSS.

That is, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode 131 of the light emitting element LE through the sixth transistor T6.

The first electrode of the first transistor T1 may be electrically connected to the data line DL through the second transistor T2.

The gate electrode of the first transistor T1 may be electrically connected to the first power line VDL through the pixel capacitor PC1. That is, the pixel capacitor PC1 may be electrically connected between the gate electrode of the first transistor T1 and the first power line VDL.

Accordingly, the potential of the gate electrode of the first transistor T1 may be maintained by the first power ELVDD of the first power line VDL.

When a data signal Vdata of the data line DL is transmitted to the first electrode of the first transistor T1 through the turned-on second transistor T2, a voltage difference between the gate electrode of the first transistor T1 and the first electrode of the first transistor T1 may correspond to the first power ELVDD and the data signal Vdata.

In this case, when the voltage difference between the gate electrode of the first transistor T1 and the first electrode of the first transistor T1, i.e., the gate-to-source voltage difference becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light emitting element LE between the first power line VDL and the second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The second transistor T2 may be electrically connected between the first electrode of the first transistor T1 and the data line DL. The second transistor T2 may be turned on by the scan write signal GW of the scan write line GWL.

The third transistor T3 may be electrically connected between the gate electrode of the first transistor T1 and the second electrode of the first transistor T1. The third transistor T3 may be turned on by the scan write signal GW of the scan write line GWL.

The third transistor T3 may include a plurality of sub-transistors connected in series. For example, the third transistor T3 may include a first sub-transistor T31 and a second sub-transistor T32. In this way, it is possible to prevent the potential of the gate electrode of the first transistor T1 from changing due to the leakage current through the third transistor T3 that is turned off.

The fourth transistor T4 may be connected between the gate electrode of the first transistor T1 and the initialization power line VIL. The fourth transistor T4 may be turned on by the scan initialization signal GI of the scan initialization line GIL.

The fourth transistor T4 may include a plurality of sub-transistors connected in series. For example, the fourth transistor T4 may include a third sub-transistor T41 and a fourth sub-transistor T42. In this way, it is possible to prevent the potential of the gate electrode of the first transistor T1 from changing due to the leakage current through the fourth transistor T4 that is turned off.

The fifth transistor T5 may be electrically connected between the first electrode of the first transistor T1 and the first power line VDL.

The sixth transistor T6 may be electrically connected between the second electrode of the first transistor T1 and the anode electrode 131 of the light emitting element LE.

The fifth transistor T5 and the sixth transistor T6 may be turned on by the emission control signal EC of the emission control line ECL.

The seventh transistor T7 may be electrically connected between the anode electrode 131 of the light emitting element LE and the initialization power line VIL. The seventh transistor T7 may be turned on by the gate control signal GC of the gate control line GCL.

As shown in FIG. 5, the first to seventh transistors T1 to T7 may be provided as P-type MOSFETs. However, this is merely an example, and some of the first to seventh transistors T1 to T7 may be provided as N-type MOSFETs. That is, according to other embodiments, the third and fourth transistors T3 and T4 among the first to seventh transistors T1 to T7 may be provided as N-type MOSFETs.

FIG. 6 is a cross-sectional view illustrating a first transistor, a sixth transistor, and a light emitting element shown in FIG. 5.

Referring to FIG. 6, the display device 100 according to some embodiments may include the substrate 110, the circuit layer 120 on the substrate 110, the element layer 130 on the circuit layer 120, the encapsulation layer 140 on the element layer 130, and the touch sensor layer 150 on the encapsulation layer 140.

In addition, the display device 100 according to some embodiments may further include the polarization layer 160 located on the touch sensor layer 150.

According to some embodiments, the touch sensor layer 150 may be located on a touch buffer layer covering the encapsulation layer 140.

The substrate 110 may be formed of an insulating material such as a polymer resin. For example, the substrate 110 may contain polyimide.

As shown in FIG. 6, according to some embodiments, the circuit layer 120 may include a first semiconductor layer CH1, S1, D1, CH6, S6, and D6 located on the substrate 110, a first gate insulating layer 122 covering the first semiconductor layer, a first gate conductive layer G1 and G6 located on the first gate insulating layer 122, a second gate insulating layer 123 covering the first gate conductive layer, a second gate conductive layer CAE located on the second gate insulating layer 123, a first interlayer insulating layer 124 covering the second gate conductive layer, a first source-drain conductive layer ANDE1 located on the first interlayer insulating layer 124, a first planarization layer 125 covering the first source-drain conductive layer, a second source-drain conductive layer ANDE2 located on the first planarization layer 125, and a second planarization layer 126 covering the second source-drain conductive layer.

According to some embodiments, the circuit layer 120 may further include a buffer layer 121 covering the substrate 110. In this case, the first semiconductor layer may be located on the buffer layer 121.

The circuit layer 120 may include the light emitting pixel drivers EPD that are respectively electrically connected to the light emitting elements LE located in the emission areas EA, and wires for transmitting various signals and voltages to the light emitting pixel drivers EPD. The light emitting pixel drivers EPD may include the first transistor T1 and two or more of the transistors T2 to T7 electrically connected to the first transistor T1.

According to some embodiments, the first transistor T1 may include a channel portion CH1, a source portion S1, and a drain portion D1 located in the first semiconductor layer on the substrate 110, and a gate electrode G1 located in the first gate conductive layer on the first gate insulating layer 122 covering the first semiconductor layer. The source portion S1 and the drain portion D1 may be connected to both ends of the channel portion CH1. The source portion S1 and the drain portion D1 may be doped at a higher concentration than the channel portion CH1. The gate electrode G1 may overlap the channel portion CH1.

Similarly, the sixth transistor T6 may include a channel portion CH6, a source portion S6, and a drain portion D6 located in the first semiconductor layer on the substrate 110, and a gate electrode G6 located in the first gate conductive layer on the first gate insulating layer 122 covering the first semiconductor layer.

According to some embodiments, the second to fifth transistors T2 to T5 and the seventh transistor T7 have substantially the same structure as the first transistor T1 and the sixth transistor T6, and therefore, some redundant description may be omitted below.

The pixel capacitor PC1 may be provided as an overlapping area between the gate electrode G1 of the first transistor T1 and a pixel capacitor electrode CAE. The pixel capacitor electrode CAE may be located on a second gate conductive layer on the second gate insulating layer 123 covering the first gate conductive layer.

The anode electrode 131 of the element layer 130 may be electrically connected to the drain portion D6 of the sixth transistor T6 through a first anode connection electrode ANDE1 and a second anode connection electrode ANDE2.

The first anode connection electrode ANDE1 may be located on a first source-drain conductive layer on a first interlayer insulating layer 124 covering the second gate conductive layer. The first anode connection electrode ANDE1 may be electrically connected to the drain portion D6 of the sixth transistor T6 through a first anode contact hole ANCT1 penetrating the first interlayer insulating layer 124, the second gate insulating layer 123, and the first gate insulating layer 122.

The second anode connection electrode ANDE2 may be located on a second source-drain conductive layer on the first planarization layer 125 covering the first source-drain conductive layer. The second anode connection electrode ANDE2 may be electrically connected to the first anode connection electrode ANDE1 through a second anode contact hole ANCT2 penetrating the first planarization layer 125.

The element layer 130 may include the light emitting elements LE located on the second planarization layer 126 and respectively corresponding to the emission areas EA.

Each of the light emitting elements LE may include the anode electrode 131 and the cathode electrode 134 facing each other, and a light emitting layer 133 located therebetween.

Alternatively, each of the light emitting elements LE may further include a first common layer 135 located between the anode electrode 131 and the light emitting layer 133, and a second common layer 136 located between the light emitting layer 133 and the cathode electrode 134.

That is, the element layer 130 may include the anode electrodes 131 respectively corresponding to the emission areas EA, a pixel defining layer 132 corresponding to a non-emission area NEA and covering the edge of the anode electrode 131, the light emitting layers 133 respectively located on the anode electrodes 131, and the cathode electrode 134 located on the light emitting layers 133 and the pixel defining layer 132.

The anode electrode 131 may be located in each of the emission areas EA and may be electrically connected to one light emitting pixel driver EPD of the circuit layer 120. This anode electrode 131 may be referred to as a pixel electrode.

The anode electrode 131 may be electrically connected to the second anode connection electrode ANDE2 through a third anode contact hole ANCT3 penetrating the second planarization layer 126.

The light emitting layer 133 may be formed of an organic light emitting material that converts electron-hole pairs into light.

The encapsulation layer 140 may be located on the circuit layer 120 and cover the element layer 130.

The encapsulation layer 140 may include a first encapsulation layer 141 located on the element layer 130 and made of an inorganic insulating material, a second encapsulation layer 142 located on the first encapsulation layer 141, overlapping the element layer 130, and made of an organic insulating material, and a third encapsulation layer 143 located on the first encapsulation layer 141, covering the second encapsulation layer 142, and made of an inorganic insulating material.

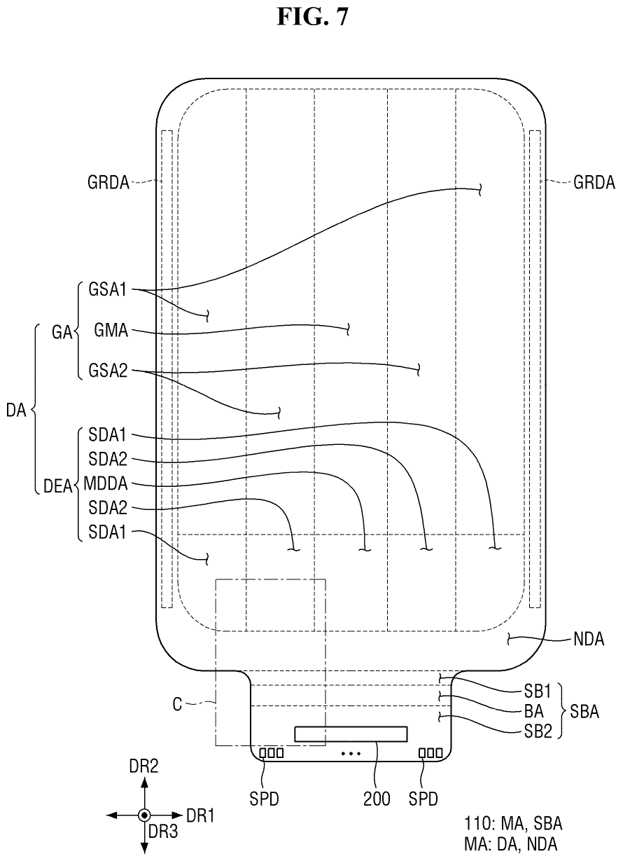

FIG. 7 is a plan view illustrating the substrate of FIG. 3 according to some embodiments.

Referring to FIG. 7, the substrate 110 of the display device 100 according to some embodiments includes the main region MA corresponding to the display surface, and the sub-region SBA protruding from one side of the main region MA.

The main region MA may include the display area DA located at most of the center, and the non-display area NDA located at the periphery to surround the display area DA.

The display area DA may include a bypass area DEA located on one side adjacent to the sub-region SBA, and a general area GA located in the remaining area excluding the bypass area DEA.

The bypass area DEA may include a bypass middle area MDDA located at the center in the first direction DR1, a first bypass side area SDA1 parallel to the bypass middle area MDDA in the first direction DR1 and in contact with the non-display area NDA, and a second bypass side area SDA2 located between the bypass middle area MDDA and the first bypass side area SDA1.

The first bypass side area SDA1 may be located adjacent to the bent corner of the substrate 110 as compared to the bypass middle area MDDA and the second bypass side area SDA2.

The first bypass side area SDA1 and the second bypass side area SDA2 may be located between the bypass middle area MDDA and the non-display area NDA on both sides of the bypass middle area MDDA in the first direction DR1.

The general area GA may include a general middle area GMA connected to the bypass middle area MDDA of the bypass area DEA in the second direction DR2, a first general side area GSA1 connected to the first bypass side area SDA1 of the bypass area DEA in the second direction DR2, and a second general side area GSA2 connected to the second bypass side area SDA2 of the bypass area DEA in the second direction DR2.

The non-display area NDA may include a gate driving circuit area GDRA where a gate driving circuit is located.

The gate driving circuit area GDRA may be located in a portion of the non-display area NDA adjacent to at least one side of the display area DA in the first direction DR1.

The gate driving circuit of the gate driving circuit area GDRA may sequentially transmit gate signals to gate lines. Here, the gate lines may include the scan write line GWL (see FIG. 5) that transmits the scan write signal GW (see FIG. 5), the scan initialization line GIL (see FIG. 5) that transmits the scan initialization signal GI (see FIG. 5), the gate control line GCL (see FIG. 5) that transmits the gate control signal GC (see FIG. 5), the bias control line GBL (see FIG. 5) that transmits the bias control signal GB (see FIG. 5), and the emission control line ECL (see FIG. 5) that transmits the emission control signal EC (see FIG. 5).

The sub-region SBA may include a bending region BA that is transformed into a bending shape, a first sub-region SB1 located between one side of the bending region BA and the main region MA, and a second sub-region SB2 connected to the other side of the bending region BA.

When the bending region BA is transformed into a bending shape, the second sub-region SB2 is located below the substrate 110 and overlaps the main region MA.

A display driving circuit 200 may be located in the second sub-region SB2.

The signal pads SPD bonded to a circuit board 300 may be located at one edge of the second sub-region SB2.

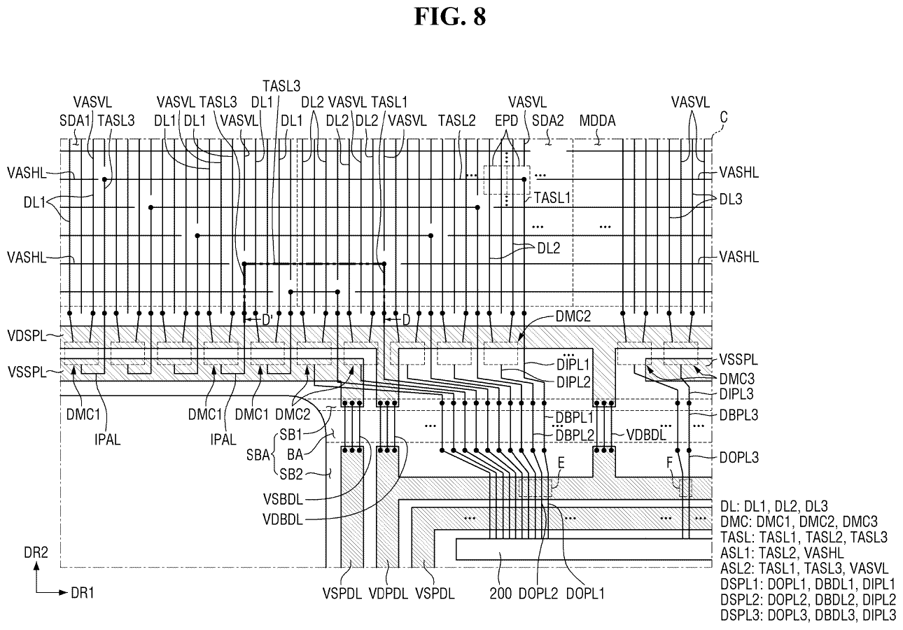

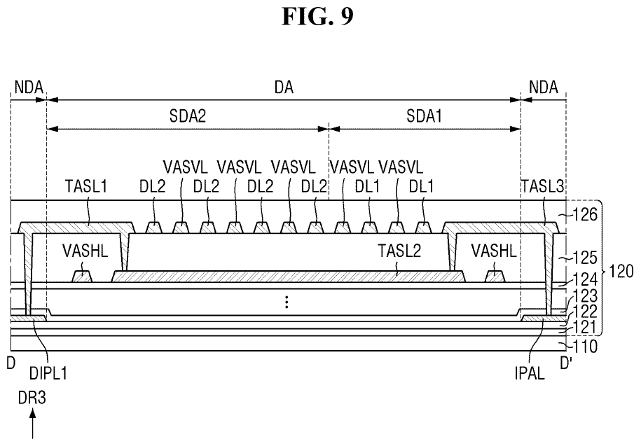

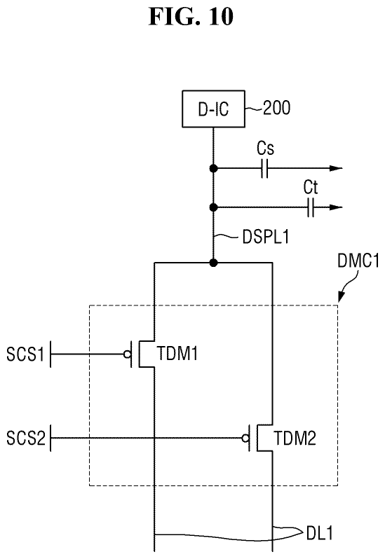

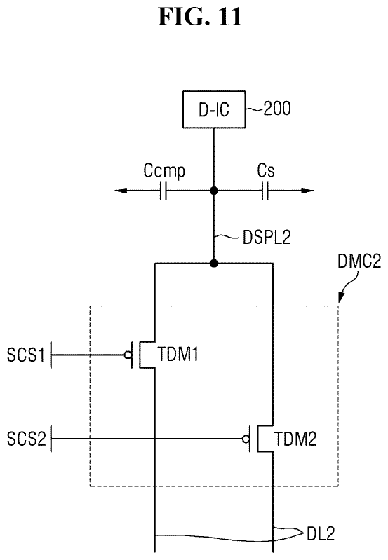

FIG. 8 is a layout diagram showing part C of FIG. 7 according to some embodiments. FIG. 9 is a cross-sectional view taken along the line D-D′ of FIG. 8. FIG. 10 is an equivalent circuit diagram showing a transmission path between a display driving circuit and a first demux circuit of FIG. 8. FIG. 11 is an equivalent circuit diagram showing a transmission path between a display driving circuit and a second demux circuit of FIG. 8.

Referring to FIG. 8, the circuit layer 120 of the display device 100 according to some embodiments may include the light emitting pixel drivers EPD arranged in the first and second directions DR1 and DR2 and respectively electrically connected to the light emitting elements LE of the element layer 130, the data lines DL extending in the second direction DR2 and transmitting the data signal Vdata (see FIG. 5) to the light emitting pixel drivers EPD, demux circuits DMC located in the non-display area NDA and outputting the data signal Vdata of the data lines DL based on a data mux signal supplied from the display driving circuit 200, and data transmission lines DSPL electrically connected between the display driving circuit 200 and the demux circuits DMC and respectively transmitting data mux signals of the demux circuits DMC.

The demux circuits DMC may include a first demux circuit DMC1 located adjacent to the edge of the substrate 110 in the first direction DR1, and a second demux circuit DMC2 spaced further apart from the edge of the substrate 110 than the first demux circuit DMC1 in the first direction DR1.

The data lines DL may include first data lines DL1 located in the first bypass side area SDA1 adjacent to the edge of the substrate 110 in the first direction DR1, and second data lines DL2 located in the second bypass side area SDA2 between the first bypass side area SDA1 and the bypass middle area MDDA.

The first data lines DL1 may be electrically connected to the output terminals of the first demux circuit DMC1.

The second data lines DL2 may be electrically connected to the output terminals of the second demux circuit DMC2.

The data transmission lines DSPL may include a first data transmission line DSPL1 transmitting a data mux signal of the first demux circuit DMC1 and electrically connected to the input terminal of the first demux circuit DMC1, and a second data transmission line DSPL2 transmitting a data mux signal of the second demux circuit DMC2 and electrically connected to the input terminal of the second demux circuit DMC2.

The data transmission lines DSPL may extend to a part of the non-display area NDA between the sub-region SBA, and the second bypass side area SDA2 and the bypass middle area MDDA.

That is, the first data transmission line DSPL1 transmitting a data mux signal of the first demux circuit DMC1 may extend to the second bypass side area SDA2, rather than extending to the first demux circuit DMC1 adjacent to the first bypass side area SDA1.

Accordingly, the first data transmission line DSPL1 may be located adjacent to the second demux circuit DMC2.

As an example, one first data transmission line DSPL1 may extend between two adjacent second demux circuits DMC2.

In addition, the first data transmission line DSPL1 may be electrically connected to the input terminal of the first demux circuit DMC1 through a bypass line TASL located in the display area DA and an input auxiliary line IPAL located in the non-display area NDA.

On the other hand, the second data transmission line DSPL2 may be directly electrically connected to the second demux circuit DMC2.

The bypass auxiliary line TASL may include a first bypass auxiliary line TASL1 extending in the second direction DR2, paired with one of the second data lines DL2 connected to the second demux circuit DMC2, and electrically connected to the first data transmission line DSPL1, a second bypass auxiliary line TASL2 extending in the first direction DR1 and electrically connected to the first bypass auxiliary line TASL1, and a third bypass auxiliary line TASL3 extending in the second direction DR2, paired with one of the first data lines DL1 connected to the first demux circuit DMC1, and electrically connected to the second bypass auxiliary line TASL2.

The input auxiliary line IPAL may electrically connect the third bypass auxiliary line TASL3 to the input terminal of the first demux circuit DMC1.

The first bypass auxiliary line TASL1 may extend in the second direction DR2 between the first data transmission line DSPL1 and the second bypass auxiliary line TASL2.

Because the first bypass auxiliary line TASL1 is paired with one of the second data lines DL2 electrically connected to the output terminals of the second demux circuit DMC2, the first data transmission line DSPL1 may be located adjacent to the second demux circuit DMC2.

The second bypass auxiliary line TASL2 may extend in the first direction DR1 between the first bypass auxiliary line TASL1 and the third bypass auxiliary line TASL3.

The third bypass auxiliary line TASL3 may extend in the second direction DR2 between the second bypass auxiliary line TASL2 and the input auxiliary line IPAL.

According to some embodiments, the circuit layer 120 may further include first auxiliary lines ASL1 extending in the first direction DR1, and second auxiliary lines ASL2 extending in the second direction DR2 and respectively paired with the data lines DL.

The first auxiliary lines ASL1 may overlap the light emitting pixel drivers EPD of the display area DA. That is, the number of first auxiliary lines ASL1 may be the number of columns each including the emission areas EA arranged in the first direction DR1.

The data lines DL and the second auxiliary lines ASL2 may be arranged alternately one by one in the first direction DR1.

The second auxiliary lines ASL2 may include the first bypass auxiliary line TASL1 and the third bypass auxiliary line TASL3 extending in the second direction DR2 of the bypass auxiliary line TASL.

The first auxiliary lines ASL1 may include the second bypass auxiliary line TASL2 extending in the first direction DR1 of the bypass auxiliary line TASL.

In addition, in order to reduce the visibility of each of the first bypass auxiliary line TASL1, the second bypass auxiliary line TASL2, and the third bypass auxiliary line TASL3, the first auxiliary lines ASL1 may further include power auxiliary horizontal lines VASHL, and the second auxiliary lines ASL2 may further include power auxiliary vertical lines VASVL.

The power auxiliary horizontal lines VASHL and the power auxiliary vertical lines VASVL may transmit at least one of the first power ELVDD, the second power ELVSS, or the initialization voltage VINT. As an example, the power auxiliary horizontal lines VASHL and the power auxiliary vertical lines VASVL may transmit the second power ELVSS. In another example, some of the power auxiliary horizontal lines VASHL and some of the power auxiliary vertical lines VASVL may transmit the secondary power ELVSS, and some others of the power auxiliary horizontal lines VASHL and some others of the power auxiliary vertical lines VASVL may transmit the initialization voltage VINT.

Referring to FIG. 9, the data lines DL and the second auxiliary lines ASL2 (TASL1, TASL3, and VASVL) may be located on at least one insulating layer 127 covering the first auxiliary lines ASL1 (TASL2 and VASHL).

As an example, the first auxiliary lines ASL1 may be located in the first source-drain conductive layer on the first interlayer insulating layer 124, and the data lines DL and the second auxiliary lines ASL2 may be located in the second source-drain conductive layer on the first planarization layer 125 covering the first source-drain conductive layer.

The second bypass auxiliary line TASL2 may be electrically connected to each of the first bypass auxiliary line TASL1 and the third bypass auxiliary line TASL3 through a connection hole penetrating the first planarization layer 125.

According to some embodiments, the data transmission lines DSPL and the input auxiliary line IPAL may be located in the first gate conductive layer on the first gate insulating layer 122 or in the second gate conductive layer on the second gate insulating layer 123.

As shown in FIG. 8, according to some embodiments, the demux circuits DMC may further include a third demux circuit DMC3 that is spaced further apart from the edge of the substrate 110 than the second demux circuit DMC2 in the first direction DR1.

The data transmission lines DSPL may further include a third data transmission line DSPL3 transmitting a data mux signal of the third demux circuit DMC3 and electrically connected to the input terminal of the third demux circuit DMC3.

The data lines DL may further include third data lines DL3 located in the bypass middle area MDDA.

The third data lines DL3 may be electrically connected to the output terminals of the third demux circuit DMC3.

According to some embodiments, the data transmission lines DSPL1, DSPL2, and DSPL3 may include data output lines DOPL1, DOPL2, and DOPL3 located in the second sub-region SB2 and extending from the display driving circuit 200 to the bending region BA, data bending lines DBDL1, DBDL2, and DBDL3 located in the bending region BA and electrically connected to the data output lines DOPL1, DOPL2, and DOPL3, and data input lines DIPL1, DIPL2, and DIPL3 located in the first sub-region SB1 and the non-display area NDA and electrically connected to the data bending lines DBDL1, DBDL2, and DBDL3, respectively.

The data input line DIPL1 of the first data transmission line DSPL1 may be electrically connected to the first bypass auxiliary line TASL1.

The data input line DIPL2 of the second data transmission line DSPL2 may be electrically connected to the input terminal of the second demux circuit DMC2, and the data input line DIPL3 of the third data transmission line DSPL3 may be electrically connected the input terminal of the third demux circuit DMC3.

According to some embodiments, the circuit layer 120 may further include power pad lines VDPDL and VSPDL extending to the bending region BA from a part, which transmits the first power ELVDD and the second power ELVSS, of the signal pads SPD (see FIG. 7) located in the second sub-region SB2.

The power pad lines VDPDL and VSPDL may include a first power pad line VDPDL for transmitting the first power ELVDD and a second power pad line VSPDL for transmitting the second power ELVSS.

In addition, the circuit layer 120 may further include power bending lines VDBDL and VSBDL located in the bending region BA and electrically connected to the power pad lines VDPDL and VSPDL, and power supply lines VDSPL and VSSPL located in the non-display area NDA and the first sub-region SB1 and electrically connected to the power bending lines VDBDL and VSBDL.

The power bending lines VDBDL and VSBDL may include a first power bending line VDBDL electrically connected to the first power pad line VDPDL, and a second power bending line VSBDL electrically connected to the second power pad line VSPDL.

The power supply lines VDSPL and VSSPL may include a first power supply line VDSPL electrically connected to the first power bending line VDBDL, and a second power supply line VSSPL electrically connected to the second power bending line VSBDL.

According to some embodiments, the data transmission lines DSPL may extend only to a part of the non-display area NDA between the sub-region SBA, and the second bypass side area SDA2 and the bypass middle area MDDA.

That is, the second data transmission line DSPL2 may extend to the second demux circuit DMC2, and the third data transmission line DSPL3 may extend to the third demux circuit DMC3.

In addition, the first data transmission line DSPL1 may extend to the first bypass auxiliary line TASL1, which is paired with the second data line DL2 of the second bypass side area SDA2, rather than to the first demux circuit DMC1.

In this way, the extension length of the data transmission lines DSPL may be reduced, which may be advantageous in reducing the width of the non-display area NDA.

However, as the first data transmission line DSPL1 is electrically connected to the first demux circuit DMC1 through the bypass line TASL and the input auxiliary line IPAL, the transmission path between the first demux circuit DMC1 and the display driving circuit 200 further includes the bypass line TASL and the input auxiliary line IPAL as well as the first data transmission line DSPL1.

On the other hand, because the second data transmission line DSPL2 is directly electrically connected to the second demux circuit DMC2, the transmission path between the second demux circuit DMC2 and the display driving circuit 200 includes only the second data transmission line DSPL2.

That is, the transmission path between the second demux circuit DMC2 and the display driving circuit 200 has a shorter length than the transmission path between the first demux circuit DMC1 and the display driving circuit 200. Accordingly, as the difference in length of the transmission paths between the demux circuits DMC and the display driving circuit 200 increases, the deviation of the data signal Vdata transmitted to the data lines DL may increase, thereby causing a luminance deviation.

In order to prevent this, according to some embodiments, the second data transmission line DSPL2 may be electrically connected to a path compensation capacitor Ccmp (see FIG. 11).

Referring to FIGS. 10 and 11, each of the demux circuits DMC may include two or more demux transistors TDM1 and TDM2 electrically connected between the display driving circuit 200 and two or more data lines DL, respectively.

In each of the demux circuits DMC, the two or more demux transistors TDM1 and TDM2 may be turned on for different periods, so that a data mux signal supplied from the display driving circuit 200 may be time-divided by the demux circuit DMC, and supplied as a data signal to the two or more data lines DL.

As an example, each of the demux circuits DMC may include a first demux transistor TDM1 turned on by a first demux control signal SCS1, and a second demux transistor TDM2 turned on by a second demux control signal SCS2.

According to some embodiments, the input terminal of the first demux circuit DMC1 may be electrically connected to the first data transmission line DSPL1 through the bypass auxiliary line TASL and the input auxiliary line IPAL.

Accordingly, as shown in FIG. 10, the capacitance of the transmission path between the first demux circuit DMC1 and the display driving circuit 200 may include a capacitance Cs due to the first data transmission line DSPL1 and a capacitance Ct due to the bypass auxiliary line TASL and the input auxiliary line IPAL.

Meanwhile, the input terminal of the second demux circuit DMC2 may be directly electrically connected to the second data transmission line DSPL2.

If the capacitance of the transmission path between the second demux circuit DMC2 and the display driving circuit 200 includes only the capacitance Cs due to the second data transmission line DSPL2, the deviation of signal distortion by the transmission paths between the demux circuits DMC and the display driving circuit 200 may increase, resulting in a large luminance deviation.

However, as shown in FIG. 11, according to some embodiments, the second data transmission line DSPL2 is electrically connected to the path compensation capacitor Ccmp.

In this way, the capacitance of the transmission path between the second demux circuit DMC2 and the display driving circuit 200 may be compensated similarly to the capacitance of the transmission path between the first demux circuit DMC1 and the display driving circuit 200, as it further includes the capacitance of the path compensation capacitor Ccmp as well as the capacitance Cs due to the second data transmission line DSPL2.

Accordingly, the deviation of signal distortion caused by the transmission paths between the demux circuits DMC and the display driving circuit 200 may become smaller, and thus the luminance deviation may be reduced.

According to some embodiments, the path compensation capacitor Ccmp may be located in the second sub-region SB2 of the sub-region SBA. In this way, an increase in the width of the non-display area NDA due to the placement of the path compensation capacitor Ccmp may be prevented.

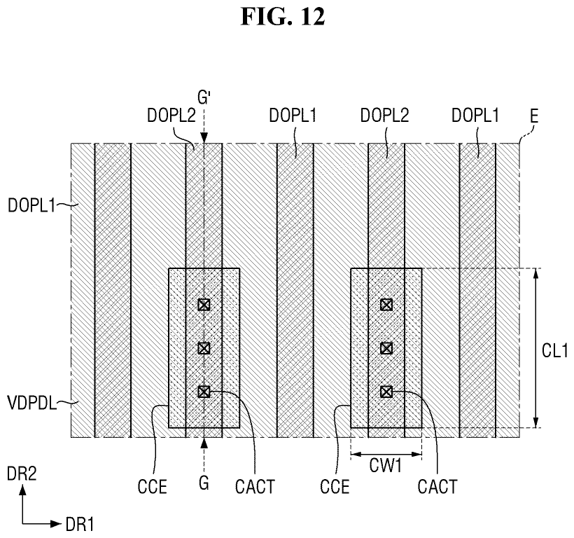

Hereinafter, with reference to FIGS. 12 to 16, the path compensation capacitor Ccmp according to each embodiment will be described.

In FIGS. 12 to 16, for simplicity of description, a case where the power pad line is the first power pad line VDPDL will be described by way of example. However, this is merely an example, and the power pad line may be any wire that is applied with a constant voltage, such as the first power ELVDD, the second power ELVSS, and the initialization voltage VINT, and is located in the second sub-region SB2.

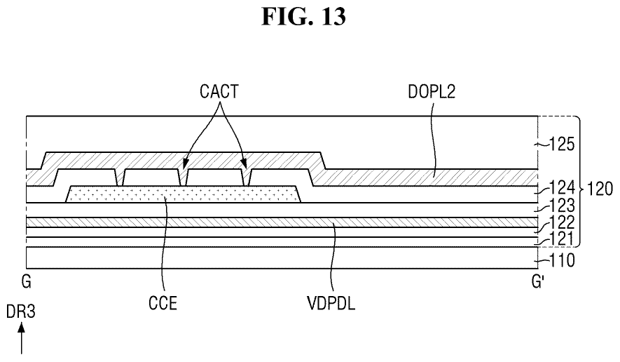

FIG. 12 is a plan view showing part E of FIG. 8 according to some embodiments. FIG. 13 is a cross-sectional view taken along the line G-G′ of FIG. 12.

Referring to FIG. 12, the circuit layer 120 according to some embodiments may further include a compensation capacitor electrode CCE located in the second sub-region SB2 and electrically connected to the data output line DOPL2 of the second data transmission line DSPL2.

The compensation capacitor electrode CCE may be electrically connected to the data output line DOPL2 of the second data transmission line DSPL2 through at least one capacitor auxiliary contact hole CACT.

The power pad line VDPDL may overlap the compensation capacitor electrode CCE and the second data transmission line DSPL2. Accordingly, the path compensation capacitor Ccmp may be provided by the overlapping area between the power pad line VDPDL and each of the compensation capacitor electrode CCE and the data output line DOPL2 of the second data transmission line DSPL2 and.

As an example, the compensation capacitor electrode CCE electrically connected to the data output line DOPL2 of the second data transmission line DSPL2 may be located with a first width CW1 and a first length CL1.

The capacitance of the path compensation capacitor Ccmp may correspond to the width of the overlapping area between the compensation capacitor electrode CCE and the power pad line VDPDL.

As shown in FIG. 13, according to some embodiments, the data output line DOPL2 of the second data transmission line DSPL2 may be located in the first source-drain conductive layer on the first interlayer insulating layer 124.

That is, the first source-drain conductive layer on the first interlayer insulating layer 124 may include the data output lines DOPL1, DOPL2, and DOPL3 of the data transmission lines DSPL.

In addition, the first gate conductive layer on the first gate insulating layer 122 may include the power pad line VDPDL.

The second gate conductive layer on the second gate insulating layer 123 may include the compensation capacitor electrode CCE.

In this case, the capacitor auxiliary contact hole CACT for electrical connection between the data output line DOPL2 of the second data transmission line DSPL2 and the compensation capacitor electrode CCE may penetrate the first interlayer insulating layer 124.

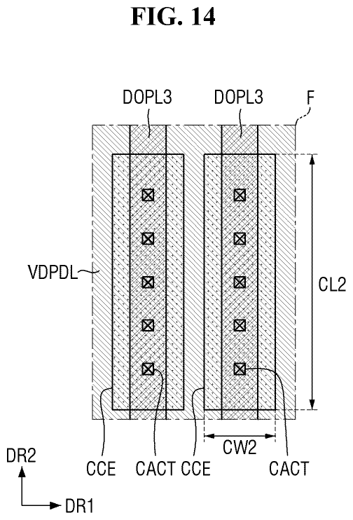

FIG. 14 is a plan view showing part F of FIG. 8 according to some embodiments.

As previously shown in FIG. 8, the third data transmission line DSPL3 transmitting a data mux signal of the third demux circuit DMC3 electrically connected to the third data lines DL3 of the bypass middle area MDDA is directly electrically connected to the input terminal of the third demux circuit DMC3.

Therefore, according to some embodiments, in order to reduce the deviation of signal distortion caused by the transmission paths between the display driving circuit 200 and the demux circuits DMC, the third data transmission line DSPL3 may be electrically connected to the path compensation capacitor Ccmp.

Referring to FIG. 14, the path compensation capacitor Ccmp electrically connected to the third data transmission line DSPL3 is substantially the same as the path compensation capacitor Ccmp electrically connected to the second data transmission line DSPL2 shown in FIGS. 12 and 13, except that it is electrically connected to the data output line DOPL3 of the third data transmission line DSPL3 and is located with a second width CW2 and a second length CL2. Therefore, some redundant description may be omitted below.

According to some embodiments, the third demux circuit DMC3 is spaced further apart from the edge of the substrate 110 than the second demux circuit DMC2 in the first direction DR1. In other words, the third demux circuit DMC3 is located closer to the display driving circuit 200 than the second demux circuit DMC2, so that the extension length of the third data transmission line DSPL3 may be shorter than the extension length of the second data transmission line DSPL2.

As a result, the capacitance of the transmission path between the third demux circuit DMC3 and the display driving circuit 200 may be smaller than the capacitance of the transmission path between the second demux circuit DMC2 and the display driving circuit 200.

In order to compensate for this, according to some embodiments, when the data output line DOPL2 of the second data transmission line DSPL2 is electrically connected to a first path compensation capacitor, the data output line DOPL3 of the third data transmission line DSPL3 may be electrically connected to a second path compensation capacitor having a larger capacitance than the first path compensation capacitor.

As shown in FIG. 12, the compensation capacitor electrode CCE of the first path compensation capacitor electrically connected to the data output line DOPL2 of the second data transmission line DSPL2 may be located with the first width CW1 and the first length CL1.

On the other hand, as shown in FIG. 14, the compensation capacitor electrode CCE of the second path compensation capacitor electrically connected to the data output line DOPL3 of the third data transmission line DSPL3 may be located with the second width CW2 and the second length CL2.

The second width CW2 may be greater than or equal to the first width CW1.

The second length CL2 may be greater than or equal to the first length CL1.

Further, although not separately shown, according to some embodiments, as the length of the transmission paths between the display driving circuit 200 and the demux circuits DMC is shorter, the path compensation capacitor Ccmp of greater capacitance may be electrically connected to the data transmission line DSPL.

In this way, the deviation of signal distortion caused by the transmission paths between the display driving circuit 200 and the demux circuits DMC may be prevented from occurring due to the path compensation capacitor Ccmp.

Meanwhile, according to some embodiments as shown in FIGS. 12, 13, and 14, the compensation capacitor electrode CCE is located in the second gate conductive layer on the second gate insulating layer 123, and the power pad line VDPDL is located in the first gate conductive layer on the first gate insulating layer 122. However, this is merely an example, and according to some embodiments, any variation may be made as long as the compensation capacitor electrode CCE, the power pad line VDPDL, and the data output lines DOPL1, DOPL2, and DOPL3 are located in different conductive layers. That is, the compensation capacitor electrode CCE may be located in one of the first gate conductive layer and the second gate conductive layer, and the power pad line VDPDL may be located in the other of the first gate conductive layer and the second gate conductive layer. In other words, the compensation capacitor electrode CCE may be located in the first gate conductive layer on the first gate insulating layer 122, and the power pad line VDPDL may be located in the second gate conductive layer on the second gate insulating layer 123.

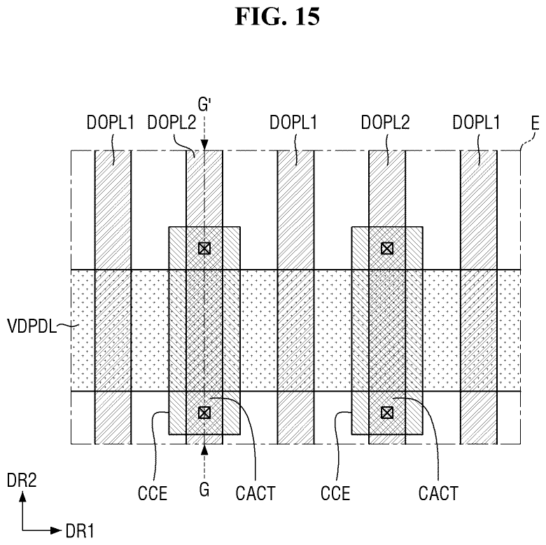

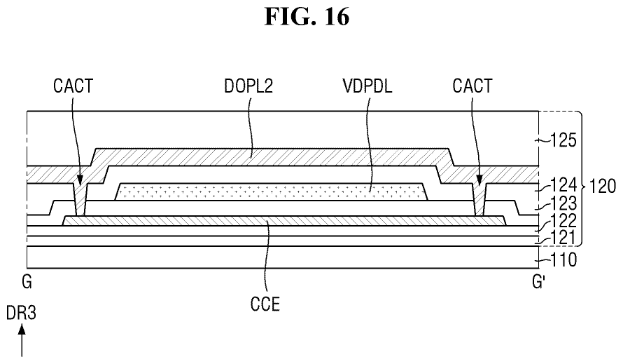

FIG. 15 is a plan view showing part E of FIG. 8 according to some embodiments. FIG. 16 is a cross-sectional view taken along the line G-G′ of FIG. 15.

The display device 100 according to some embodiments as shown in FIGS. 15 and 16 is substantially the same as that of the embodiments shown in FIGS. 1 to 14, except that the compensation capacitor electrode CCE is located in the first gate conductive layer on the first gate insulating layer 122, and the power pad line VDPDL is located in the second gate conductive layer on the second gate insulating layer 123. Therefore, some redundant description may be omitted below.

Meanwhile, as described above, some of the transistors in each of the light emitting pixel drivers EPD may be provided as N-type MOSFETs, and the others may be provided as P-type MOSFETs.

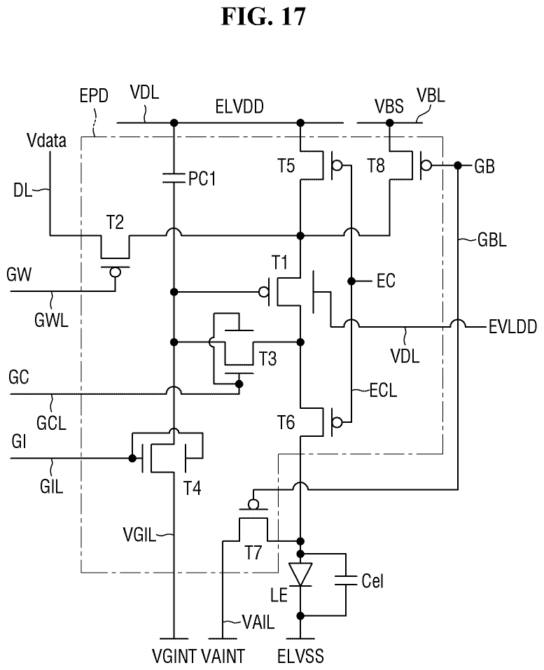

FIG. 17 is an equivalent circuit diagram showing the light emitting pixel driver of FIG. 4 according to other embodiments.

Referring to FIG. 17, the light emitting pixel driver EPD according to other embodiments is substantially the same as that of the embodiments shown in FIG. 5, except that it further includes an eighth transistor T8 electrically connected between the first electrode of the first transistor T1 and a bias line VBL for transmitting a bias voltage VBS, and the third transistor T3 and the fourth transistor T4 are provided as N-type MOSFETs. Therefore, some redundant description may be omitted below.

The second transistor T2 and the third transistor T3 are turned on by different signals. Specifically, the second transistor T2 may be turned on by the scan write signal GW of the scan write line GWL, and the third transistor T3 may be turned on by the gate control signal GC of the gate control line GCL.

The fourth transistor T4 may be electrically connected between the gate electrode of the first transistor T1 and a gate initialization voltage line VGIL for transmitting a gate initialization voltage VGINT.

The fourth transistor T4 may be turned on by the scan initialization signal GI of the scan initialization line GIL.

The seventh transistor T7 may be electrically connected between the anode electrode 131 of the light emitting element LE and an anode initialization voltage line VAIL for transmitting an anode initialization voltage VAINT.

The seventh transistor T7 may be turned on by the bias control signal GB of the bias control line GBL.

The eighth transistor T8 may be turned on by the bias control signal GB of the bias control line GBL. By the turned-on eighth transistor T8, the potential of the first electrode of the first transistor T1 may be maintained at the bias voltage VBS.

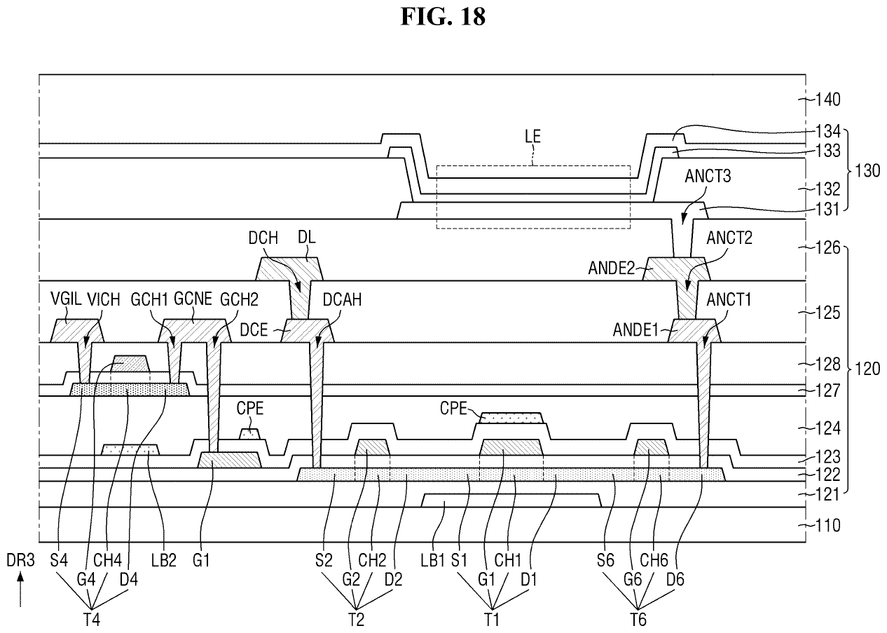

FIG. 18 is a cross-sectional view showing the first transistor, the second transistor, the fourth transistor, the sixth transistor, and the light emitting element of FIG. 17.

Referring to FIG. 18, the circuit layer 120 of the display device 100 according to other embodiments is substantially the same as that of the embodiments shown in FIG. 6, except that it further includes a second semiconductor layer CH4, S4, and D4 located on the first interlayer insulating layer 124, a third gate insulating layer 127 covering the second semiconductor layer, a third gate conductive layer G4 located on the third gate insulating layer 127, and a second interlayer insulating layer 128 covering the third gate conductive layer, and the first source-drain conductive layer is located on the second interlayer insulating layer 128. Therefore, some redundant description may be omitted below.

According to other embodiments, in order to be provided as a different type from the first transistor T1, the second transistor T2, and the sixth transistor T6, the fourth transistor T4 may include a channel portion CH4, a source portion S4, and a drain portion D4 located in the second semiconductor layer on the first interlayer insulating layer 124, and a gate electrode G4 located in the third gate conductive layer on the third gate insulating layer 127.

The first source-drain conductive layer on the second interlayer insulating layer 128 may further include the gate initialization voltage line VGIL, a gate connection electrode GCNE, and a data connection electrode DCE.

The gate initialization voltage line VGIL may be electrically connected to the source portion S4 of the fourth transistor T4 through an initialization connection hole VICH.

The gate connection electrode GCNE may be electrically connected to the drain portion D4 of the fourth transistor T4 through a first gate connection hole GCH1, and may be electrically connected to the gate electrode G1 of the first transistor T1 through a second gate connection hole GCH2.

The second source-drain conductive layer on the first planarization layer 125 may include the data line DL.

The data line DL may be electrically connected to the data connection electrode DCE through the data connection hole DCH.

The data connection electrode DCE may be electrically connected to a source portion S2 of the second transistor T2 through a data auxiliary connection hole DCAH.

According to other embodiments, the circuit layer 120 may further include a first light blocking layer LB1 located on the substrate 110 while overlapping the channel portion CH1 of the first transistor T1, and a second light blocking layer LB2 located in the second gate conductive layer on the second gate insulating layer 123 while overlapping the channel portion CH4 of the fourth transistor T4.

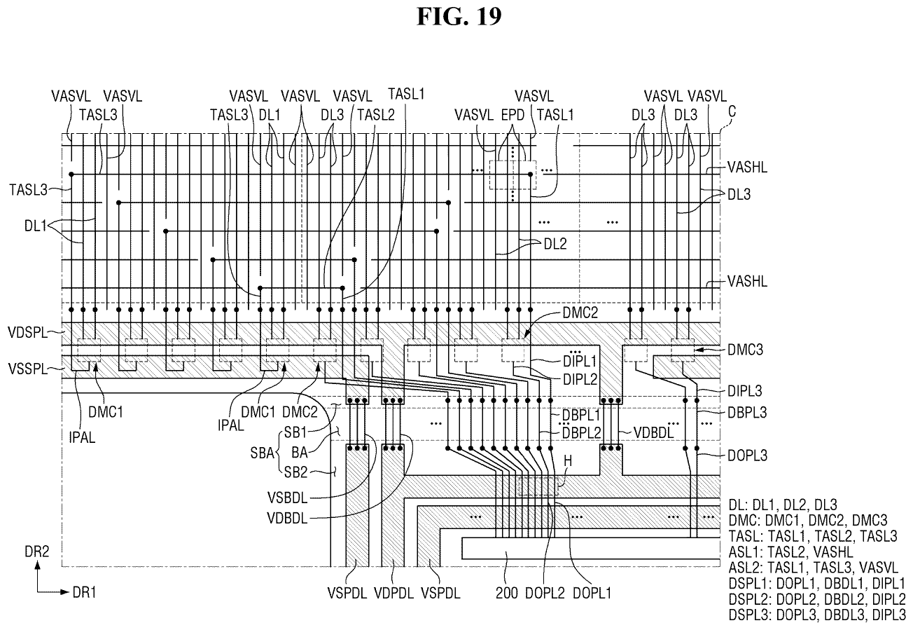

FIG. 19 is a layout diagram showing part C of FIG. 7 according to other embodiments.

Referring to FIG. 19, the display device 100 according to other embodiments is substantially the same as that of the embodiments shown in FIG. 8, except that the data lines DL and the second auxiliary lines ASL2 are arranged alternately two by two in the first direction DR1, and two first data transmission lines DSPL1 extend between two adjacent second demux circuits DMC2. Therefore, some redundant description may be omitted below.

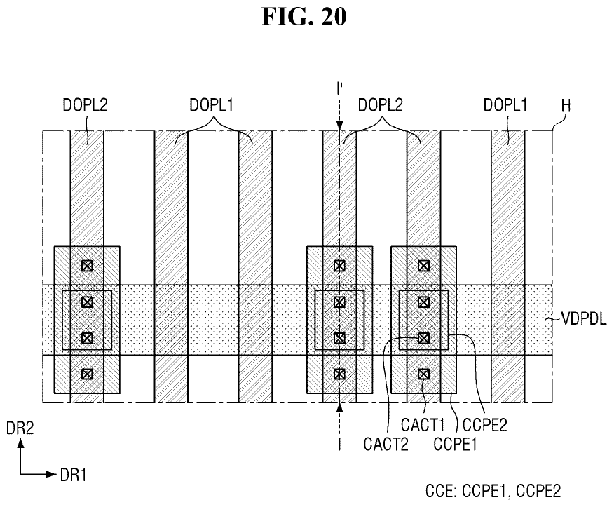

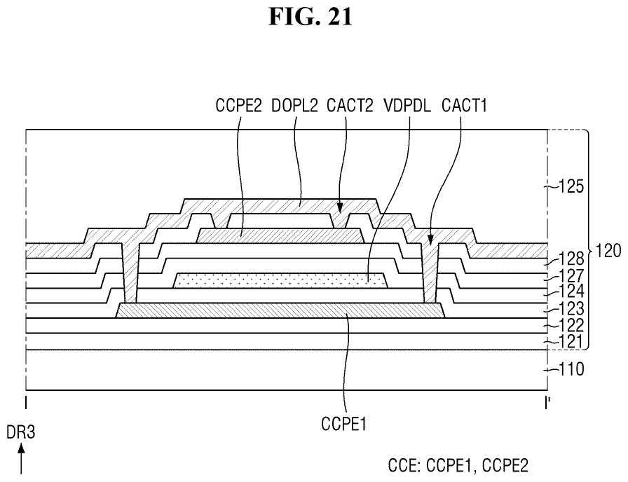

FIG. 20 is a plan view showing part H of FIG. 19 according to some embodiments. FIG. 21 is a cross-sectional view taken along the line I-I′ of FIG. 20.

According to some embodiments as shown in FIGS. 20 and 21, the compensation capacitor electrode CCE may include a first capacitor division electrode CCPE1 and a second capacitor division electrode CCPE2 which are located in different conductive layers.

The first capacitor division electrode CCPE1 may be located in the first gate conductive layer on the first gate insulating layer 122, and may be electrically connected to the data output line DOPL2 of the second data transmission line DSPL2 through at least one first capacitor auxiliary contact hole CACT1. The at least one first capacitor auxiliary contact hole CACT1 may penetrate the second interlayer insulating layer 128, the third gate insulating layer 127, the first interlayer insulating layer 124, and the second gate insulating layer 123.

The second capacitor division electrode CCPE2 may be located in the third gate conductive layer on the third gate insulating layer 127, and may be electrically connected to the data output line DOPL2 of the second data transmission line DSPL2 through at least one second capacitor auxiliary contact hole CACT2. The at least one second capacitor auxiliary contact hole CACT2 may penetrate the second interlayer insulating layer 128.

The power pad line VDPDL may be located in the second gate conductive layer on the second gate insulating layer 123.

Accordingly, the path compensation capacitor Ccmp may be provided by the overlapping area between the first capacitor division electrode CCPE1 and the power pad line VDPDL, and the overlapping area between the second capacitor division electrode CCPE2 and the power pad line VDPDL. Therefore, it may become easy to provide the path compensation capacitor Ccmp of larger capacity.

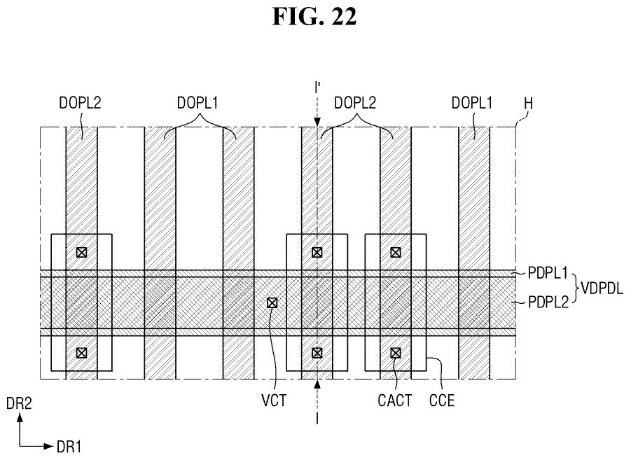

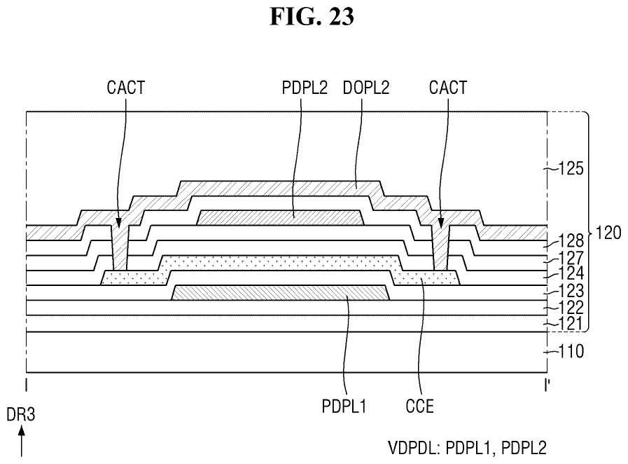

FIG. 22 is a plan view showing part H of FIG. 19 according to some embodiments. FIG. 23 is a cross-sectional view taken along the line I-I′ of FIG. 22.

According to some embodiments as shown in FIGS. 22 and 23, the power pad line VDPDL may include a first pad division line PDPL1 and a second pad division line PDPL2 which are located in different conductive layers.

The first pad division line PDPL1 may be located in the first gate conductive layer on the first gate insulating layer 122.

The second pad division line PDPL2 may be located in the third gate conductive layer on the third gate insulating layer 127.

The second pad division line PDPL2 may be electrically connected to the first pad division line PDPL1 through a power auxiliary connection hole VCT. The power auxiliary connection hole VCT may penetrate the third gate insulating layer 127, the first interlayer insulating layer 124, and the second gate insulating layer 123.

The compensation capacitor electrode CCE may be located in the second gate conductive layer on the second gate insulating layer 123.

Accordingly, the path compensation capacitor Ccmp may be provided by the overlapping area between the first pad division line PDPL1 and the compensation capacitor electrode CCE, the overlapping area between the second pad division line PDPL2 and the compensation capacitor electrode CCE, and the overlapping area between the second pad division line PDPL2 and the data output line DOPL2 of the second data transmission line DSPL2.

Therefore, it may become easier to provide the path compensation capacitor Ccmp of larger capacity.

However, the effects of the present disclosure are not restricted to the one set forth herein. The above and other effects of the present disclosure will become more apparent to one of daily skill in the art to which the present disclosure pertains by referencing the appended claims, and their equivalents.

What is claimed is:

1. A display device comprising:
a substrate;
a circuit layer on the substrate; and
an element layer on the circuit layer,
wherein the substrate comprises a main region comprising a display area in which emission areas are arranged and a non-display area around the display area, and a sub-region protruding from one side of the main region,
the element layer comprises light emitting elements respectively in the emission areas, and
the circuit layer comprises:
light emitting pixel drivers electrically connected to the light emitting elements, respectively, and arranged in a first direction and a second direction;
data lines extending in the second direction, and transmitting a data signal to the light emitting pixel drivers;
demux circuits in the non-display area, and configured to output the data signal of the data lines based on a data mux signal supplied from a display driving circuit; and
data transmission lines electrically connected between the display driving circuit and the demux circuits, and configured to transmit data mux signals of the demux circuits, respectively,
wherein the data transmission lines comprise:
a first data transmission line electrically connected to a first demux circuit adjacent to an edge of the substrate in the first direction; and
a second data transmission line electrically connected to a second demux circuit spaced further apart from the edge of the substrate than the first demux circuit in the first direction,
wherein the second data transmission line is electrically connected to a path compensation capacitor in the sub-region.

2. The display device of claim 1, wherein the data lines comprise:
first data lines electrically connected to demux output lines of the first demux circuit; and
second data lines electrically connected to demux output lines of the second demux circuit,
the circuit layer further comprises:
a first bypass auxiliary line extending in the second direction, paired with one of the second data lines, and electrically connected to the first data transmission line;
a second bypass auxiliary line extending in the first direction, and electrically connected to the first bypass auxiliary line;
a third bypass auxiliary line extending in the second direction, paired with one of the first data lines, and electrically connected to the second bypass auxiliary line; and
an input auxiliary line in the non-display area, and electrically connected between the third bypass auxiliary line and the first demux circuit, and
the second data transmission line is directly electrically connected to the second demux circuit.

3. The display device of claim 2, wherein the sub-region comprises a bending region having a bent shape, a first sub-region between the main region and one side of the bending region, and a second sub-region connected to the other side of the bending region,
the display driving circuit is in the second sub-region,
the circuit layer further comprises a power pad line extending from a part of the signal pads in the second sub-region to the bending region, and
each of the data transmission lines comprises:
a data output line in the second sub-region, and extending from the display driving circuit to the bending region;
a data bending line in the bending region, and electrically connected to the data output line; and
a data input line in the first sub-region and the non-display area, and electrically connected to the data bending line,
wherein the path compensation capacitor is electrically connected between the data output line of the second data transmission line and the power pad line.

4. The display device of claim 3, wherein the data transmission lines further comprise a third data transmission line electrically connected to a third demux circuit spaced further apart from the edge of the substrate than the second demux circuit in the first direction,
the data output line of the second data transmission line is electrically connected to a first path compensation capacitor, and
the data output line of the third data transmission line is electrically connected to a second path compensation capacitor having a larger capacitance than that of the first path compensation capacitor and in the sub-region.

5. The display device of claim 3, wherein the circuit layer further comprises a compensation capacitor electrode in the second sub-region and electrically connected to the data output line of the second data transmission line, and
the path compensation capacitor is provided by an overlapping area between the power pad line and each of the compensation capacitor electrode and the data output line of the second data transmission line.

6. The display device of claim 5, wherein the circuit layer comprises:
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a first source-drain conductive layer on the first interlayer insulating layer; and
a first planarization layer covering the first source-drain conductive layer,
wherein the first source-drain conductive layer comprises the data output line of each of the data transmission lines.

7. The display device of claim 6, wherein the first gate conductive layer comprises the power pad line,
the second gate conductive layer comprises the compensation capacitor electrode, and
the compensation capacitor electrode is electrically connected to the data output line of the second data transmission line through at least one capacitor auxiliary contact hole penetrating the first interlayer insulating layer.

8. The display device of claim 6, wherein the first gate conductive layer comprises the compensation capacitor electrode,
the second gate conductive layer comprises the power pad line, and
the compensation capacitor electrode is electrically connected to the data output line of the second data transmission line through at least one capacitor auxiliary contact hole penetrating the second gate insulating layer and the first interlayer insulating layer.

9. The display device of claim 6, wherein the circuit layer further comprises:
a second semiconductor layer on the first interlayer insulating layer;
a third gate insulating layer covering the second semiconductor layer;
a third gate conductive layer on the third gate insulating layer; and
a second interlayer insulating layer covering the third gate conductive layer,
wherein the first source-drain conductive layer is on the second interlayer insulating layer.

10. The display device of claim 9, wherein the compensation capacitor electrode comprises a first capacitor division electrode and a second capacitor division electrode in different conductive layers,
the first gate conductive layer comprises the first capacitor division electrode,
the second gate conductive layer comprises the power pad line,
the third gate conductive layer comprises the second capacitor division electrode,
the first capacitor division electrode is electrically connected to the data output line of the second data transmission line through at least one capacitor auxiliary contact hole penetrating the second interlayer insulating layer, the third gate insulating layer, the first interlayer insulating layer, and the second gate insulating layer, and
the second capacitor division electrode is electrically connected to the data output line of the second data transmission line through at least one second capacitor auxiliary contact hole penetrating the second interlayer insulating layer.

11. The display device of claim 9, wherein the power pad line comprises a first pad division line and a second pad division line in different conductive layers,
the first gate conductive layer comprises the first pad division line,
the second gate conductive layer comprises the compensation capacitor electrode,
the third gate conductive layer comprises the second pad division line, and
the compensation capacitor electrode is electrically connected to the data output line of the second data transmission line through at least one capacitor auxiliary contact hole penetrating the first interlayer insulating layer.

12. The display device of claim 3, wherein the power pad line comprises:
a first power pad line configured to transmit a first power; and
a second power pad line configured to transmit a second power,
wherein the first power and the second power are configured to drive the light emitting element.

13. The display device of claim 1, wherein each of the demux circuits comprises demux transistors electrically connected between one of the data transmission lines and two or more of the data lines, and
the demux transistors comprise:
a first demux transistor configured to be turned on by a first demux control signal; and
a second demux transistor configured to be turned on by a second demux control signal.

14. A display device comprising:
a substrate;
a circuit layer on the substrate; and
an element layer on the circuit layer,
wherein the substrate comprises a main region comprising a display area in which emission areas are arranged and a non-display area around the display area, and a sub-region protruding from one side of the main region,
the element layer comprises light emitting elements respectively in the emission areas, and
the circuit layer comprises:
light emitting pixel drivers electrically connected to the light emitting elements, respectively, and arranged in a first direction and a second direction;
data lines extending in the second direction, and configured to transmit a data signal to the light emitting pixel drivers;
demux circuits in the non-display area, and configured to output the data signal of the data lines based on a data mux signal supplied from a display driving circuit; and
data transmission lines electrically connected between the display driving circuit and the demux circuits, and configured to transmit data mux signals of the demux circuits, respectively,
wherein the demux circuits comprise a first demux circuit adjacent to an edge of the substrate in the first direction, and a second demux circuit spaced further apart from the edge of the substrate than the first demux circuit in the first direction,
the data transmission lines comprise a first data transmission line configured to transmit a data mux signal of the first demux circuit, and a second data transmission line configured to transmit a data mux signal of the second demux circuit,
the first data transmission line is electrically connected to the first demux circuit through a bypass line in the display area and an input auxiliary line in the non-display area, and
the second data transmission line is directly electrically connected to the second demux circuit, and electrically connected to a path compensation capacitor in the sub-region.

15. The display device of claim 14, wherein the sub-region comprises a bending region having a bent shape, a first sub-region between the main region and one side of the bending region, and a second sub-region connected to the other side of the bending region,
the display driving circuit is in the second sub-region,
the circuit layer further comprises a power pad line extending from a part of signal pads in the second sub-region to the bending region, and
each of the data transmission lines comprises:
a data output line in the second sub-region, and extending from the display driving circuit to the bending region;
a data bending line in the bending region, and electrically connected to the data output line; and
a data input line in the first sub-region and the non-display area, and electrically connected to the data bending line,
wherein the path compensation capacitor is electrically connected between the data output line of the second data transmission line and the power pad line.

16. The display device of claim 15, wherein the demux circuits further comprise a third demux circuit spaced further apart from the edge of the substrate than the second demux circuit in the first direction, and
the data transmission lines further comprise a third data transmission line transmitting a data mux signal of the third demux circuit,
the circuit layer further comprises:
a first compensation capacitor electrode in the second sub-region, overlapping the power pad line, and electrically connected to the data output line of the second data transmission line; and
a second compensation capacitor electrode in the second sub-region, overlapping the power pad line, and electrically connected to the data output line of the second data transmission line,
wherein an overlapping area between the second compensation capacitor electrode and the power pad line has a larger width than that of an overlapping area between the first compensation capacitor electrode and the power pad line.

17. The display device of claim 15, wherein the path compensation capacitor is provided by an overlapping area between the power pad line and each of the data output line of the second data transmission line and a compensation capacitor electrode electrically connected to the data output line of the second data transmission line, and
the circuit layer comprises:
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a first source-drain conductive layer on the first interlayer insulating layer; and
a first planarization layer covering the first source-drain conductive layer,
wherein the first source-drain conductive layer comprises the data output line of each of the data transmission lines,
one of the first gate conductive layer and the second gate conductive layer comprises the power pad line, and
the other of the first gate conductive layer and the second gate conductive layer comprises the compensation capacitor electrode.

18. The display device of claim 15, wherein the path compensation capacitor is provided by an overlapping area between the power pad line and each of the data output line of the second data transmission line and the compensation capacitor electrode electrically connected to the data output line of the second data transmission line, and
the circuit layer comprises:
a first semiconductor layer on the substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a second semiconductor layer on the first interlayer insulating layer;
a third gate insulating layer covering the second semiconductor layer;
a third gate conductive layer on the third gate insulating layer;
a second interlayer insulating layer covering the third gate conductive layer;
a first source-drain conductive layer on the second interlayer insulating layer; and
a first planarization layer covering the first source-drain conductive layer,
wherein the first source-drain conductive layer comprises the data output line of each of the data transmission lines.

19. The display device of claim 18, wherein the compensation capacitor electrode comprises a first capacitor division electrode and a second capacitor division electrode in different conductive layers,
the first gate conductive layer comprises the first capacitor division electrode,
the second gate conductive layer comprises the power pad line, and
the third gate conductive layer comprises the second capacitor division electrode.

20. The display device of claim 18, wherein the power pad line comprises a first pad division line and a second pad division line in different conductive layers,
the first gate conductive layer comprises the first pad division line,
the second gate conductive layer comprises the compensation capacitor electrode, and
the third gate conductive layer comprises the second pad division line.
